(19) United States
(12) Patent Application Publication
(10) Pub. No.: US 2025/0273618 A1
(43) Pub. Date: Aug. 28, 2025

(54) THERMAL COMPRESSION BONDING WITH CONTACT AREA ADJUSTMENT

(71) Applicant: International Business Machines Corporation, Armonk, NY (US)

(72) Inventors: Prabudhya Roy Chowdhury, Albany, NY (US); Katsuyuki Sakuma, Fishkill, NY (US); Sathyanarayanan Raghavan, Ballston Lake, NY (US)

(21) Appl. No.: 18/588,848

(22) Filed: Feb. 27, 2024

(51) Int. Cl. H01L 23/00

(52) U.S. Cl. CPC H01L 24/75; H01L 24/16; H01L 2224/16145; H01L 2224/75303

(57) ABSTRACT

A thermal compression bonding apparatus and assembly are provided in which the contact area between a thermal compression bonding head nozzle and a semiconductor component that is closest to the thermal compression bonding head nozzle has been modified/adjusted to mitigate temperature non-uniformity from the center to the corner of the semiconductor component. This mitigation in temperature non-uniformity improves the uniformity of bonding quality across the semiconductor package.

### BACKGROUND

The present application relates to thermal compression bonding in which the contact area between a thermal compression bonding head nozzle and a semiconductor component that is closest to the thermal compression bonding head nozzle has been modified to mitigate temperature non-uniformity from the center to the corner of the semiconductor component.

As electronic devices including semiconductor devices have been designed to be increasingly light weight and compact, the semiconductor packages used therein have become more highly integrated and smaller in size. Thus, a chip stack package in which multiple layers of integrated circuitry are vertically stacked has been widely used for increasing the chip density in a small sized package. In general, the chips and the circuit board of the chip stack package are interconnected by an overall interconnection, such as a bump structure and a penetration electrode, not by a peripheral interconnection such as a lead frame and a wire bonding structure. Thus, the number of the connection pins can be increased and the size of the circuit board can be reduced in the chip stack package. As a result, the chip density and the operational reliability of the chip stack package are remarkably increased as compared with the conventional semiconductor packages.

Bonding of a chip to a chip, a die to a die or a die to an organic substrate in a wafer level package process may be performed by a thermal compression process. In the chip to chip case, a second chip is mounted on a first chip and the second chip is compressed onto to the first chip by a bonding tool while heat is transferred to a bump structure of the second chip to melt the bumps. However, the temperature of the bonding tool is not uniform throughout the bonding tool. Thus, the heat transfer to the bump structure from the bonding tool is not uniform, and a temperature deviation may occur between the central bump structure and the peripheral bump structure of the chip. The temperature deviation usually gives rise to insufficient melting of the peripheral bump structures, and as a result, bonding failures frequently occur between the first chip and the second chip.

### SUMMARY

An apparatus/assembly for thermal compression bonding is provided in which the contact area between a thermal compression bonding head nozzle and a semiconductor component that is closest to the thermal compression bonding head nozzle has been modified to mitigate temperature non-uniformity from the center to the corner of the semiconductor component.

In one aspect of the present application, an apparatus is provided that includes a thermal compression bonding head nozzle including a first region and a second region located on a first side of the thermal compression bonding head nozzle that is configured to face a semiconductor component. The first region includes at least one recessed area surrounded by a semiconductor component contacting area. The at least one recessed area prevents contact of the semiconductor component with the thermal compression bonding head nozzle. The second region of the thermal compression bonding head nozzle surrounds the first region and has a non-semiconductor component contacting surface. The apparatus described above can be used in an assembly that includes the semiconductor component mentioned above and another semiconductor component.

In another aspect of the present application, an assembly is provided that includes a thermal compression bonding apparatus including a thermal compression bonding head nozzle including a first region and a second region located on a first side of the thermal compression bonding head nozzle. The first region includes a semiconductor component contacting area and the second region surrounds the first region and has a non-semiconductor component contacting surface. The assembly further includes a first semiconductor component having at least one recessed area present therein. The first semiconductor component and the at least on recessed area face the first side of the thermal compression bonding head nozzle. The assembly even further includes a second semiconductor component located beneath the first semiconductor component.

### BRIEF DESCRIPTION OF THE DRAWINGS

FIG. 1 is a bottom up view showing a thermal compression bonding head nozzle having recessed areas in accordance with an embodiment of the present application.

FIG. 2 is a three-dimensional (3D) depiction of the thermal compression bonding head nozzle illustrated in FIG. 1.

FIG. 3 is a cross sectional view showing a thermal compression bonding head nozzle having recessed areas in accordance with an embodiment of the present application and during an initial stage of a thermal compression bonding of a first semiconductor component with a second semiconductor component.

FIG. 4 is a cross sectional view showing a thermal compression bonding head nozzle having recessed areas that are filled with a low thermal conductivity material in accordance with an embodiment of the present application and during an initial stage of a thermal compression bonding of a first semiconductor component with a second semiconductor component.

FIG. 5 is a cross sectional view showing a prior art thermal compression bonding head nozzle and during an initial stage of a thermal compression bonding of a first semiconductor component with a second semiconductor component.

FIG. 6 is a cross sectional view showing a thermal compression bonding head nozzle without any recessed regions and during an initial stage of a thermal compression bonding of a first semiconductor component having recessed regions formed therein with a second semiconductor component.

FIG. 7 is a cross sectional view showing a thermal compression bonding head nozzle without any recessed regions and during an initial stage of a thermal compression bonding of a first semiconductor component having recessed regions formed therein that are filled with a low conductivity material with a second semiconductor component.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Experiments and modeling show that high temperature non-uniformity from center to the corner of a semiconductor component during thermal compression bonding occurs. This temperature non-uniformity creates bonding challenges. Some of these challenges include: (1) a higher temperature required to melt solder formed at the corners of a semiconductor component compared to at a center of the semiconductor component; (2) different quality intermetallic compound formation between the center and the corners; and/or (3) in-plane warpage and out-of-plane warpage that can cause non-contact defects, bridging and misalignment (this is especially critical for high density semiconductor components, fine pitch interconnects and thin interposers).

Since a thermal compression bonding head nozzle can transfer heat to the semiconductor component that is to be bonded, a thermal compression bonding apparatus and assembly are disclosed in which the contact area between a thermal compression bonding head nozzle and a semiconductor component that is closest to the thermal compression bonding head nozzle has been modified/adjusted to mitigate temperature non-uniformity from the center to the corner of the semiconductor component. This mitigation in temperature non-uniformity improves the uniformity of bonding quality across the semiconductor package. In the prior art with no recessed areas on the nozzle-semiconductor surface, there is a greater amount of heat flow at the center of the nozzle and the semiconductor die, while at the edges and corners there is lower amount of heat flow. This causes the temperature non-uniformity from center to edge as mentioned previously. By creating one or more recessed areas between the nozzle and semiconductor die contact area, higher heat flow at the center can be prevented since there is no contact to channel the heat flow. Thus, the heat flow needs to be redistributed to the edges and corners, which creates a better balance of heat flow distribution from center to edge.

In some embodiments of the present application, the contact area is altered by forming at least one recessed area in a first region of the thermal compression bonding head nozzle; the first region also includes semiconductor component contact areas that surround the at least one recessed area. In other embodiments, the contact area is altered by forming at least one recessed area in the semiconductor component that will be in direct contact with a thermal compression bonding head nozzle that has a first region composed mainly of semiconductor component contact areas. In yet other embodiments, the contact area is altered by combining a thermal compression bonding head nozzle having at least one recessed area and a semiconductor component that has at least one recessed area. Note that in the embodiments including the semiconductor component including the at least one recessed area, the recessed area in the semiconductor component faces the first side of the thermal compression bonding head nozzle that includes at least the semiconductor component contact area. These and other aspects of the present application will now be described in greater detail.

Throughout the present application, a semiconductor component denotes a semiconductor die, semiconductor chip, a semiconductor wafer or organic substrate. Each of the die, chip or wafer contains a plurality of semiconductor devices located in a front-end-of-the-line (FEOL) level. Each of the die, chip or wafer can also include a middle-of-the-line (MOL), and a backend-of-the-line (BEOL). The semiconductor component typically contains solder balls (or bumps) that are used for attaching a first semiconductor component to a second semiconductor component. In the present application, the first semiconductor component can be the same or different from the second semiconductor component. Thus in one embodiment of the present application, the first semiconductor component can be a semiconductor die, while the second semiconductor component can be a semiconductor die, semiconductor wafer or semiconductor wafer. In another embodiment of the present application, the first semiconductor component can be a semiconductor chip, while the second semiconductor component can be a semiconductor die, semiconductor wafer or semiconductor wafer. In still another embodiment of the present application, the first semiconductor component can be a semiconductor wafer, while the second semiconductor component can be a semiconductor die, semiconductor wafer or semiconductor wafer. In yet a further embodiment, the first semiconductor component can be a semiconductor die, while the second semiconductor component can be an organic substrate. The semiconductor components can be formed utilizing materials and processing techniques that are well known to those skilled in semiconductor device manufacturing.

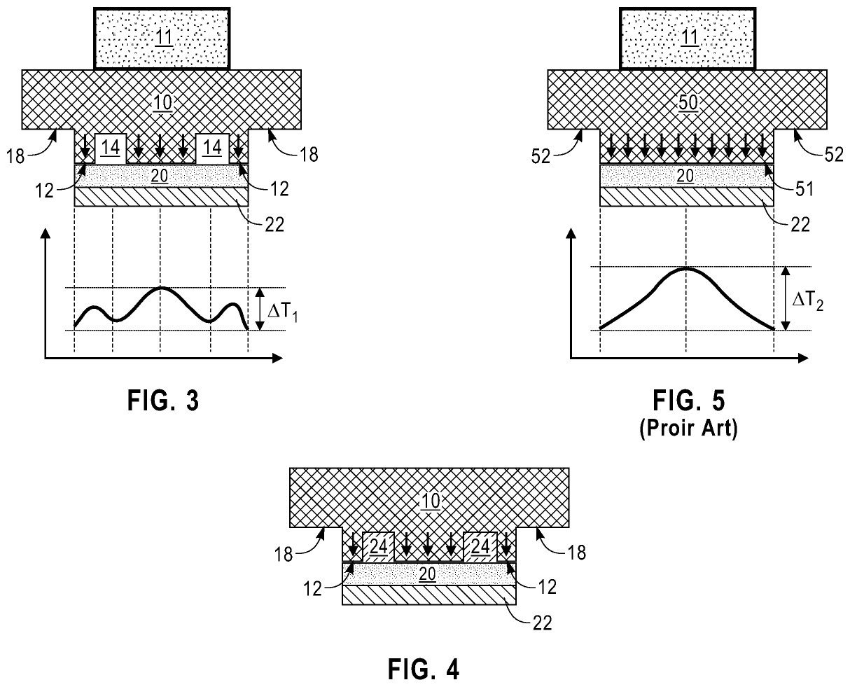

Reference will be first made to FIGS. 1, 2, 3 and 4 which depict a thermal compression bonding head nozzle 10 having recessed areas 14 in accordance with an embodiment of the present application. Notably, the thermal compression bonding head nozzle 10 illustrated in FIGS. 1, 2, 3 and 4 includes a first region (i.e., R1 in FIG. 1) and a second region (i.e., R2 in FIG. 1) located on a first side of the thermal compression bonding head nozzle 10 that is configured to face a semiconductor component (i.e., first semiconductor component 20 illustrated in FIG. 3). The first region includes at least one recessed area 14 surrounded by a semiconductor component contacting area 12. The at least one recessed area 14 prevents contact of the semiconductor component (i.e., the first semiconductor component 20 illustrated in FIG. 3 or in FIG. 4) with the thermal compression bonding head nozzle 10. The second region of the thermal compression bonding head nozzle 10 surrounds the first region and has a non-semiconductor component contacting surface 18.

In embodiments of the present application and as is illustrated FIG. 3, the thermal compression bonding head nozzle 10 has a second side that is opposite the first side in which the second side is attached to a thermal compression bonding heater 11. The thermal compression bonding heater 11 would also be located on the second side of the thermal compression bonding head nozzle 10 shown in FIGS. 1, 2 and 4. Other components/elements of the thermal compression bonding apparatus are not shown herein for clarity. In the present application, the at least one recessed area 14 can be formed by machining, grooving or laser grooving.

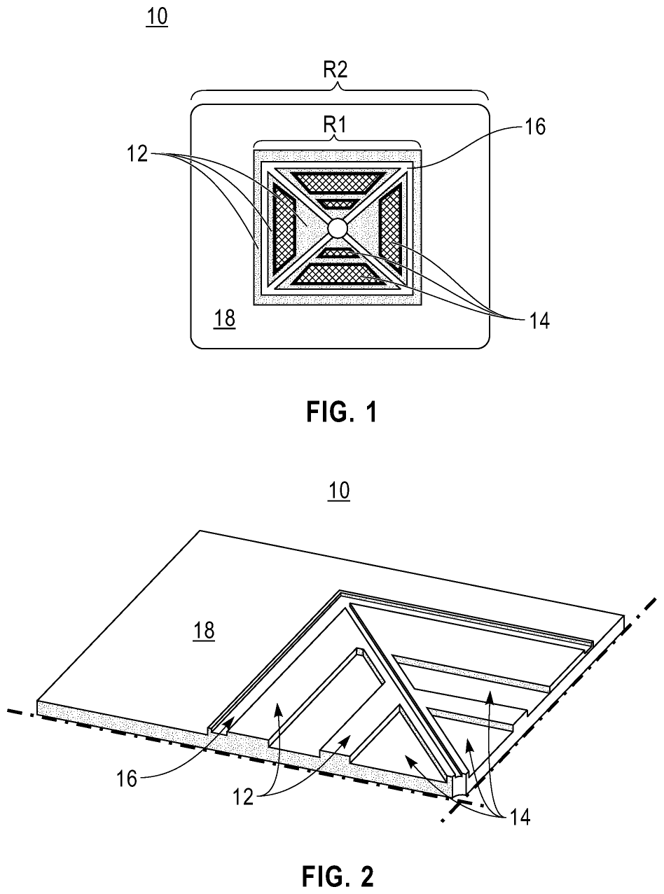

In embodiments of the present application and as is illustrated in FIGS. 1 and 2, the first region of the thermal compression bonding head nozzle 10 can also include a vacuum distribution channel 16. In the general embodiment, the vacuum distribution channel 16 does not connect to the recessed areas 14; they are separated through the semiconductor component contacting area 12 as illustrated in FIGS. 1 and 2. In an alternative embodiment, the vacuum distribution channel 16 can connect to the at least one recessed area 14 of the thermal compression bonding head nozzle 10 (not shown).

In embodiments of the present application, the thermal compression bonding head nozzle 10 is composed of a first thermal conductive material. Exemplary first thermal conductive materials that can be used in providing the thermal compression bonding head nozzle 10 include, but are not limited to, silicon carbide, silicon or stainless steel.

In some embodiments of the present application and as illustrated in FIGS. 1, 2 and 3, the at least one recessed area 14 is an air gap in which no solid material or liquid material is present. In other embodiments and as is illustrated in FIG. 4, the at least one recessed area 14 of the thermal compression bonding head nozzle 10 can be filled (partially or entirely) with a second thermal conductive material 24. The filling can include any known deposition process such as, for example, chemical vapor deposition (CVD), plasma enhanced chemical vapor deposition (PECVD), sputtering or physical vapor deposition. In some embodiments, a recess etch or a planarization process can follow the deposition of the second thermal conductive material 24.

The second thermal conductive material 24 that is present in the at least one recessed area 14 has a lower thermal conductivity than the first thermal conductive material that provides the thermal compression bonding head nozzle 10. In embodiments of the present application, the second thermal conductive material 24 has a thermal conductivity that is at least 0.5% or less, more typically 1% or less, even more typically 5% or less, and yet even more typically 10% or less, than the first thermal conductive material that provides the thermal compression bonding head nozzle 10. Exemplary second thermal conductive material 24 that can be present in the at least one recessed area 14 include, but are not limited to, silicon dioxide or silicon nitride.

In embodiments of the present application, and as shown in FIGS. 1-4, the first region which includes the semiconductor component contacting area 12, the at least one recessed area 14 and the vacuum distribution channel 16 of the thermal compression bonding head nozzle 10 is vertical offset relative to the second region of the thermal compression bonding head nozzle 10.

In the present application, the at least one recessed area 14 that is present in the thermal compression bonding head nozzle 10 has depth that does not extend down to the non-semiconductor component contacting surface 18.

Referring now to FIGS. 3 and 4, which illustrate an assembly of the present application that includes thermal compression bonding head nozzle 10 having the first area of semiconductor component contacting area 12, the at least one recessed area 14 and the vacuum distribution channel 16, first semiconductor component 20 and second semiconductor component 22 during an initial stage of a thermal compression bonding of the first semiconductor component 20 with the second semiconductor component 22; the solder balls (bumps) that will be located between the first and second semiconductor components 20 and 22, respectively, are not shown for clarity. The arrows within the thermal compression bonding head nozzle 10 illustrate the direction of heat flow through the thermal compression bonding head nozzle 10. The thermal compression bonding process employed in the present application includes processing steps that are well known to those skilled in the art. This can include placing the second semiconductor component 22 into a semiconductor component holder structure of the thermal compression bonding apparatus, and then placing the first semiconductor component 20 on top of the second semiconductor component 22. Heat and pressure is then applied to provide bonding between the first and second semiconductor components. The heating step includes a temperature that is sufficient to melt solder. An exemplary heating temperature range is from 250° C. to 400° C. The pressure is sufficient to cause intimate contact of the first semiconductor component 20 with the second semiconductor component 22.

FIG. 3 also includes a graph that shows the change in temperature, ΔT₁, from the center of the first semiconductor component 20 to the corner of the first semiconductor component 20. In FIG. 3, ΔT₁, is more uniform from the center to the corner of the first semiconductor component 20 as compared to ΔT₂ shown in FIG. 5, which is obtained using a prior art thermal compression bonding head nozzle 50 and process without any contact area adjustment. The prior art thermal compression bonding head nozzle 50 has a first side that includes a first area that has a semiconductor component contacting area 51 without any recessed area 14 present therein. The prior art thermal compression bonding head nozzle 50 also has a second area to the periphery of the first area that includes non-semiconductor component contacting surface 52. In this embodiment, there is a large temperature variation ΔT₂ from the center of to the corners of the first semiconductor component 20.

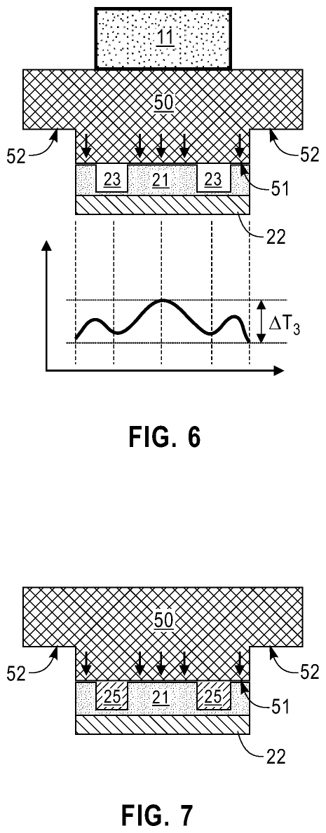

Referring now to FIGS. 6 and 7, there are illustrated a thermal compression bonding head nozzle 50 without any recessed regions and during an initial stage of a thermal compression bonding of a first semiconductor component 21 having recessed regions 23 formed therein with a second semiconductor component 22. Notably, FIGS. 6 and 7 illustrate an assembly that includes a thermal compression bonding apparatus including thermal compression bonding head nozzle 50 including a first region and a second region located on a first side of the thermal compression bonding head nozzle 50. The first region includes semiconductor component contacting area 51 and the second region surrounds the first region and has non-semiconductor component contacting surface 52. The assembly further includes first semiconductor component 21 having at least one recessed area 23 present therein. The at least one recessed area 23 faces the first side of the thermal compression bonding head nozzle 50 that includes the semiconductor component contacting area 51. The assembly even further includes second semiconductor component 22 located beneath the first semiconductor component 21. In this embodiment, the recessed area 23 that tis formed in the first semiconductor component 21 provides the contact area adjustment needed to facilitate improved and uniform heating during thermal compression bonding.

In embodiments of the present application and as is shown in FIG. 6, thermal compression bonding head nozzle 50 has a second side that is opposite the first side in which the second side is attached to a thermal compression bonding heater 11. A thermal compression bonding heater 11 would be located on the second side of the thermal compression bonding head nozzle 50 shown in FIG. 7.

In some embodiments (not shown), the thermal compression bonding head nozzle 50 shown in FIGS. 6 and 7 can be replaced with the thermal compression bonding head nozzle 10 illustrated in FIGS. 1-4. In such cases, the thermal compression bonding head nozzle 10 having at least one recessed area 14 can be used in conjunction with a first semiconductor component 21 having at least one recessed area 23. The at least one recessed area 14 can be located in regions of the first semiconductor component 21 where recessing of this semiconductor component is noter permitted or disadvantageous. The at least one recessed area 23 can be located on other regions of the first semiconductor component 21 where recessing is permitted.

In the illustrated in FIGS. 6 and 7, thermal compression bonding head nozzle 50 is composed of a first thermal conductive material. Exemplary first thermal conductive materials that can be used in providing the thermal compression bonding head nozzle 10 include, but are not limited to, silicon carbide, silicon or stainless steel.

In some embodiments, and as is illustrated in FIG. 6, the at least one recessed area 23 is an air gap. In yet other embodiments of the present application and as is illustrated in FIG. 7, the at least one recessed area is composed of a second thermal conductive material 25. The second thermal conductive material 25 can be completely or partially present in the at least one recessed area 23. The second thermal conductive material 25 used in this embodiment is the same as that described above for the second thermal conductive material 24 that can be present in the at least one recessed area 14 of the thermal compression bonding head nozzle 10.

As with the previous embodiment, the first region of the thermal compression bonding head nozzle 50 is vertical offset relative to the second region of the thermal compression bonding head nozzle 50.

FIG. 6 also includes a graph that shows the change in temperature, ΔT3, from the center of the first semiconductor component 21 to the corner of the first semiconductor substrate 21. In FIG. 6, ΔT₃ is more uniform from the center to the corner of the first semiconductor component 21 as compared to ΔT₂ shown in FIG. 5.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An apparatus comprising:
a thermal compression bonding head nozzle comprising a first region and a second region located on a first side of the thermal compression bonding head nozzle that is configured to face a semiconductor component, wherein the first region comprises at least one recessed area surrounded by a semiconductor component contacting area, wherein the at least one recessed area prevents contact of the semiconductor component with the thermal compression bonding head nozzle and wherein the second region surrounds the first region and has a non-semiconductor component contacting surface.

2. The apparatus of claim 1, wherein the thermal compression bonding head nozzle has a second side that is opposite the first side, wherein the second side is attached to a thermal compression bonding heater.

3. The apparatus of claim 1, wherein the first region further comprises a vacuum distribution channel.

4. The apparatus of claim 3, wherein the at least one recessed area is spaced apart from vacuum distribution channel by the semiconductor component contacting area.

5. The apparatus of claim 1, wherein the thermal compression bonding head nozzle is composed of a first thermal conductive material.

6. The apparatus of claim 5, further comprising a second thermal conductive material located in the at least one recessed area, with the second thermal conductive material has a lower thermal conductivity than the first thermal conductive material.

7. The apparatus of claim 1, wherein the first region of the thermal compression bonding head nozzle is vertical offset relative to the second region of the thermal compression bonding head nozzle.

8. An assembly comprising:
a thermal compression bonding apparatus comprising a thermal compression bonding head nozzle comprising a first region and a second region located on a first side of the thermal compression bonding head nozzle, wherein the first region comprises a semiconductor component contacting area and the second region surrounds the first region and has a non-semiconductor component contacting surface;
a first semiconductor component having at least one recessed area present therein, wherein the first semiconductor component and the at least one recessed area face the first side of the thermal compression bonding head nozzle; and
a second semiconductor component located beneath the first semiconductor component.

9. The assembly of claim 8, wherein the thermal compression bonding head nozzle has a second side that is opposite the first side, wherein the second side is attached to a thermal compression bonding heater.

10. The assembly of claim 8, wherein the first region further comprises at least one recessed area surrounded by the semiconductor component contacting area.

11. The assembly of claim 10, wherein the thermal compression bonding head nozzle is composed of a first thermal conductive material.

12. The assembly of claim 11, further comprising a second thermal conductive material located in the at least one recessed area, with the second thermal conductive material has a lower thermal conductivity than the first thermal conductive material.

13. The assembly of claim 10, wherein the first region further comprises a vacuum distribution channel.

14. The assembly of claim 8, wherein the thermal compression bonding head nozzle is composed of a first thermal conductive material.

15. The assembly of claim 14, further comprising a second thermal conductive material located in the at least one recessed area of the first semiconductor component, with the second thermal conductive material has a lower thermal conductivity than the first thermal conductive material.

16. The assembly of claim 8, wherein the first region of the thermal compression bonding head nozzle is vertical offset relative to the second region of the thermal compression bonding head nozzle.
